(19) United States
(12) Patent Application Publication
(10) Pub. No.: US 2024/0406651 A1
(43) Pub. Date: Dec. 5, 2024

(54) Adjustments for Dialogue Enhancement Based on Volume

(71) Applicant: Apple Inc., Cupertino, CA (US)

(72) Inventors: Adam E. Kriegel, San Jose, CA (US); Alexander D. Sanciangco, San Jose, CA (US); Afrooz Family, San Francisco, CA (US); Richard M. Powell, Mountain View, CA (US); Hilary K. Mogul, San Diego, CA (US); Vincenzo O. Giuliani, Thousand Oaks, CA (US); David Reyna, Cupertino, CA (US); Christopher J. Sanders, San Jose, CA (US)

(21) Appl. No.: 18/651,007

(22) Filed: Apr. 30, 2024

Related U.S. Application Data
(60) Provisional application No. 63/505,999, filed on Jun. 2, 2023.

(51) Int. Cl. H04S 3/00

(52) U.S. Cl. CPC H04S 3/008; H04S 2400/01; H04S 2400/13

(57) ABSTRACT

A method for processing a sound program by a playback system, in which a virtual center channel is extracted from the sound program and a dynamic range compression and a boost are applied to produce a compressed virtual center channel. This is then used to produce a speaker driver signal. Other aspects are also described and claimed.

This nonprovisional patent application claims the benefit of the earlier filing date of U.S. provisional application No. 63/505,999 filed Jun. 2, 2023.

### FIELD

An aspect of the disclosure here relates to a digital audio system that enhances the dialogue in a multi-channel sound program during playback. Other aspects are also described.

### BACKGROUND

Sound programs such as soundtracks of motion picture films and television shows, are often composed of several distinct audio components, including dialogue of characters or actors, music, and sound effects. Each of these component parts called stems may include multiple spatial channels and are mixed prior to delivery to a consumer device for playback. For example, a production company may mix a 5.1 channel dialogue stream or stem, a 5.1 music stream, and a 5.1 effects stream into a single, master 5.1 audio mix or stream. The master audio stream may thereafter be delivered to a consumer device such as a media player program executed in a console, through an online streaming service. Although mixing dialogue, music, and effects to form a single master mix or stream is convenient for purposes of distribution, this process often results in poor audio reproduction for the consumer. For example, intelligibility of dialogue may become an issue because the dialogue component for a piece of sound program content must be played back using the same settings as music and effects components since each of these components are unified in a single master stream. Dialogue intelligibility has become a growing and widely perceived problem, especially amongst movies played through a sound subsystem that has only two, left and right, loudspeakers where dialogue may be easily lost amongst music and effects.

### SUMMARY

One aspect of the disclosure here is a computerized or digital processor-implemented method for playback of a sound program, in which a virtual center channel is extracted from, via digital signal processing of, the stems of a sound program. The sound program may have arrived at the playback system in any one of various formats, such as stereo (where the stems are only left and right channels), 5.1, 7.1 or other multi-channel surround sound format, or audio object-based such as a DOLBY ATMOS format. In the case of a stereo input, an up mix is performed to produce the virtual center channel, whereas in the case of 5.1 for example the virtual center channel is simply the center channel of the 5.1 program. Next, the processor applies a dynamic range compressor to the virtual center channel, for instance only in a particular frequency band in which dialogue is found, e.g., at 800 Hz or above, followed by a boost that applies for example a make-up gain or other gain. The resulting compressed virtual center channel is then used to produce one or more speaker driver signals that drive one or more speakers (acoustic transducers) of the playback system. An assumption is that dialogue is strongly present in the virtual center channel and would therefore be enhanced by the compression and boost operations.

In one aspect, the amount or nature of the compression, the amount of boost, or both, are a function of a user volume (also referred to here as a system volume) of the playback system, which is being applied to the sound program during the playback. More specifically, at lower system volumes, the dialogue is boosted, compressed, or both, more than at higher system volumes. In another aspect, the compression and boost are applied to the sound program in response to detecting that the sound program has been tagged as being part of a movie (e.g., a soundtrack of the movie that is being played back), or in response to receiving an indication that the playback system is in a movie mode of operation and the sound program is not a system sound. A system sound may be for example a ring tone, a new message tone, or a calendar alert.

The above summary does not include an exhaustive list of all aspects of the present disclosure. It is contemplated that the disclosure includes all systems and methods that can be practiced from all suitable combinations of the various aspects summarized above, as well as those disclosed in the Detailed Description below and particularly pointed out in the Claims section. Such combinations may have advantages not specifically recited in the above summary.

### BRIEF DESCRIPTION OF THE DRAWINGS

Several aspects of the disclosure here are illustrated by way of example and not by way of limitation in the figures of the accompanying drawings in which like references indicate similar elements. It should be noted that references to “an” or “one” aspect in this disclosure are not necessarily to the same aspect, and they mean at least one. Also, in the interest of conciseness and reducing the total number of figures, a given figure may be used to illustrate the features of more than one aspect of the disclosure, and not all elements in the figure may be required for a given aspect.

FIG. 1 is a flow diagram of a method for rendering a sound program for playback, with enhanced dialogue.

FIG. 2 is a block diagram of an example digital audio system that renders a sound program for playback, with enhanced dialogue.

### DETAILED DESCRIPTION

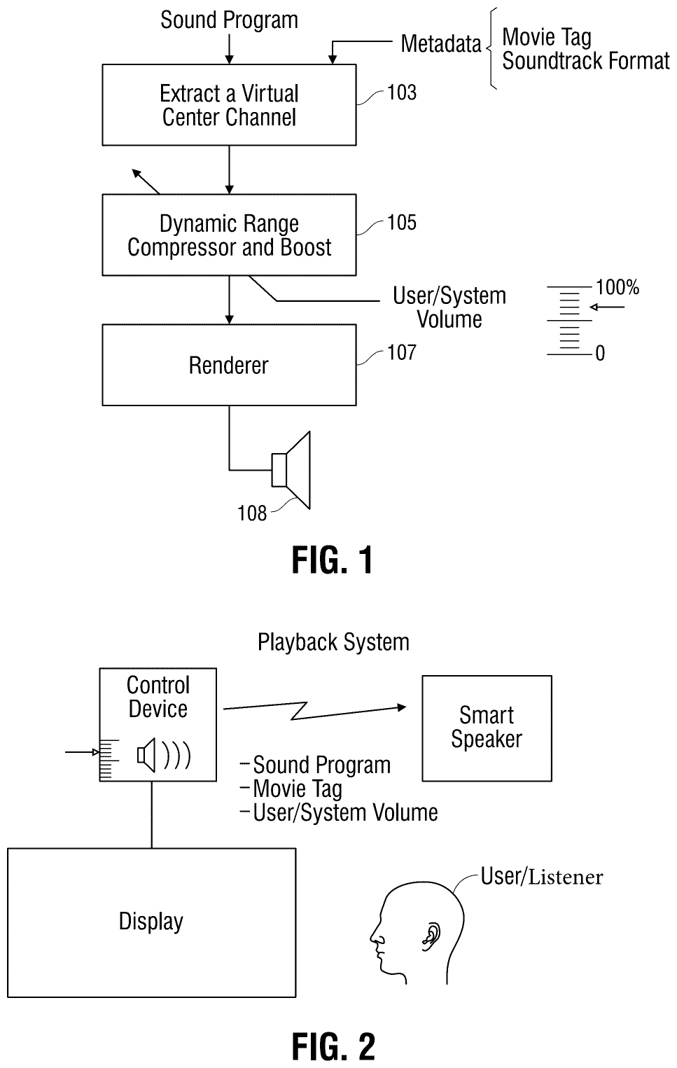

A method for processing a sound program by a playback system is depicted in the flow diagram of FIG. 1 as operations that can be performed by a programmed processor. The sound program is received, for example after having been decoded (to undo an encoding that was done for bitrate reduction) from a bitstream of a streaming media connection over the Internet. The sound program may be processed next for playback, for instance in the system depicted in FIG. 2 (to be described below.) During the playback, a virtual center channel is extracted from the sound program (operation 103.) If the sound program is in a stereo format having a left channel and a right channel, then the virtual center channel may be extracted by mixing the left channel and the right channel to produce the virtual center channel. For instance, the up mixing of the left channel and the right channel may be performed by converting the left channel and the right channel into a multi-channel format such as 5.1 surround. If the sound program is in a multi-channel surround format that has a center channel, then extracting the virtual center channel may simply be taking the center channel to be the virtual center channel.

Next in the playback processing sequence of operations is the application of a dynamic range compression and the application of a boost to the virtual center channel, to produce a compressed virtual center channel (operation 105.) In one aspect, the dynamic range compression is applied only in a particular frequency band such as above 800 Hz where dialogue is predominant, the boost is applied only in a particular frequency band, or both compression and boost are only applied in a particular frequency band in which dialogue is predominant.

After that, operation 107 is performed by a renderer which produces one or more speaker driver signals using the compressed virtual center channel and using additional audio channels of the sound program. In other words, the audio content in the compressed virtual center channel will appear in at least one speaker driver signal which drives an input of at least one acoustic transducer (a speaker 108.) The assumption here is that the virtual center channel is likely to contain dialogue, and the compression and boost operations should enhance the dialogue to make it more intelligible when output by the speaker 108.

The speaker driver signal is produced by applying, for example, to the compressed virtual center channel, a gain (e.g., a full band or wide band gain) that is in accordance with a current system volume of the playback system. The system volume may have a range of 0-100% of full scale and may be controlled manually by a user (e.g., a listener of the playback) through for example a touch panel slider, a physical switch, or via a voice command to a voice recognition based user interface of the playback system. While gain (that is applied to the compressed virtual center channel) is in accordance with the current system volume of the playback system, it is separate from the boost that is applied earlier (along with the compression for dialogue enhancement.)

In one aspect, the amount or strength of the compression, or a particular parameter of the compression, is varied during playback based on the current system volume. The dynamic range compression applied to the virtual center channel may in that case be performed by applying a first compression when the system volume is less than a set volume threshold and a second compression when the system volume is more than the set volume threshold, where the first compression is different than the second compression for example in terms of strength or a certain parameter is different.

In another aspect, the amount or strength of the boost that is applied to the virtual center channel, is varied during playback based on the current system volume. The boost applied to the virtual center channel in that case may be performed by applying a first boost when the system volume is less than a set volume threshold and a second boost when the system volume is more than the set volume threshold, the first boost being greater than the second boost.

In still another aspect, both the compression and the boost (to the virtual center channel) may be varied as described above, in effect simultaneously or in response to the same instance of the system volume. In other words, both the amount or strength of the compression, or a particular parameter of the compression, and the strength of the boost, which are applied to the virtual center channel, are varied during playback based on the current system volume. This may be based on recognizing that when the user raises the system volume to above a set threshold, the user is not as concerned with hearing the dialogue and as such the compression and boost of the virtual center channel can be “softened.” In one instance, at high system volumes of for example 90% or higher, the boost may for example be dropped to zero dB, the compression may be omitted, or the entire process in FIG. 1 may be omitted so that playback of the sound program continues without the process of FIG. 1.

In one aspect, the processor first determines whether the sound program is tagged as being a soundtrack of a movie. The dialogue enhancement process of FIG. 1 is performed only if the sound program is tagged as being a soundtrack of movie. For instance, the dialogue enhancement process would not be performed if the sound program is tagged as being music.

In another aspect, the dialogue enhancement process of FIG. 1 and as described above is performed by a processor in a smart speaker. This is illustrated in FIG. 2 where the smart speaker and a control device are in different nodes of a wireless communication network, such as a BLUETOOTH network or a wireless local area network. The smart speaker receives via the wireless communication network, from a digital media player that is executing in the control device, an indication that relates to the current system volume, the sound program, and a movie tag of the sound program or an indication that the playback system is in a movie mode of operation. Both the movie tag and the indication of movie mode of operation effectively indicate that the sound program being played back is a soundtrack of a movie. The control device may be a streaming media console that is streaming the movie (from a remote server) and has as a user interface through which the listener can control playback functions. In this example, the control device is sending the video portion of the movie that is being played back to a separate display (such as a television), while the listener is watching the movie on the display of the television and listening to the soundtrack through the smart speaker.

In another aspect, the dialogue enhancement process of FIG. 1 may be triggered manually or deliberately by the listener, or it may be triggered under certain contexts or conditions. For instance, an enhanced dialogue indication may be received (for example via the wireless communication network from the digital media player), that is separate from the movie tag or other indication that the playback system is in the movie mode of operation. The enhanced dialogue indication may have been sent by the digital media player in response to the digital media player detecting a vocalized question by the listener of the playback system, for example during playback of the sound program, e.g., “Hey Siri, what did they say?” or “I can't understand what they are saying in this movie?” The process in FIG. 1 is then performed in response to receiving the enhanced dialogue indication. In another instance, the enhanced dialogue indication may have been sent in response to the digital media player detecting that acoustic noise in an ambient environment of the playback system exceeds a threshold. In yet another instance, the enhanced dialogue indication may have been sent by the digital media player in response to it having detected that a user (e.g., the listener of the playback system) has enabled subtitles for movie playback. And in still another instance, the enhanced dialogue indication may have been sent by the digital media player in response to it having detected that a current time of day falls within a predetermined schedule, for example in the evening.

As mentioned above in connection with FIG. 2, the operations of the dialogue enhancement process depicted in FIG. 1 could be performed by a processor in the smart speaker. Alternatively, however, those operations could be performed by a processor in the control device that may also be executing a digital media player, where the control device is separate from the smart speaker, in which case the control device could alternatively send the speaker driver signals to one or more speakers, e.g., the speaker 108 in FIG. 1. The control device may be a streaming media console, a tablet computer, or a laptop computer.

Alternatively, the control device could be integrated with the display for example in a smart television, in which case the dialogue enhancement operations of FIG. 1 could be performed by a processor in the smart television; in that case, the speaker 108 (which receives the speaker driver signals as its input to reproduce the sound program) may be part of (built-into or integrated in) a smart speaker that is separate from the smart television, or it may be part of (built-in or integrated in) the smart television.

Various aspects described herein may be embodied, at least in part, in software. That is, the techniques or method operations described above may be carried out in an audio processing system in response to or by its processor executing instructions contained or stored in an electronic storage medium, such as a non-transitory machine-readable storage medium (e.g., dynamic random access memory, static memory, non-volatile memory). Note the phrase “a processor” is used generically here to refer to one or more processors that may be in separate housings or devices and that may be in communication with each other, for example forming in effect a distributed computing system. Also, in various aspects, hardwired circuitry may be used in combination with software instructions to implement some of the techniques described herein.

In the description, certain terminology is used to describe features of various aspects. For example, in certain situations, the terms “module”, “processor”, “unit”, “renderer”, “system”, “device”, “filter”, “engine”, “block,” “detector,” “simulation,” “model,” and “component”, are representative of hardware and/or software configured to perform one or more processes or functions. For instance, examples of “hardware” include, but are not limited or restricted to, an integrated circuit such as a processor (e.g., a digital signal processor, microprocessor, application specific integrated circuit, a micro-controller, etc.). Thus, different combinations of hardware and/or software can be implemented to perform the processes or functions described by the above terms, as understood by one skilled in the art. Of course, the hardware may be alternatively implemented as a finite state machine or even combinatorial logic. An example of “software” includes executable code in the form of an application, an applet, a routine, or a series of other instructions. As mentioned above, the software may be stored in any type of machine-readable medium.

Some portions of the preceding detailed descriptions may have been presented in terms of algorithms and symbolic representations of operations on data bits within a computer memory. These algorithmic descriptions and representations are the ways used by those skilled in the audio processing arts to convey the substance of their work most effectively to others skilled in the art. An algorithm is here, and, conceived to be a self-consistent sequence of operations leading to a desired result. The operations are those requiring physical manipulations of physical quantities. It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of an audio processing system, or similar electronic device, that manipulates and transforms data represented as physical (electronic) quantities within the system's registers and memories into other data similarly represented as physical quantities within the system memories or registers or other such information storage, transmission or display devices.

The processes and blocks described herein are not limited to the specific examples described and are not limited to the specific orders used as examples herein. Rather, unless specified any of the processing blocks may be re-ordered, combined, or removed, performed in parallel or in serial, as desired, to achieve the results set forth above. The processing blocks associated with implementing the audio processing system may be performed by one or more programmable processors executing one or more computer programs stored on a non-transitory computer readable storage medium to perform the functions of the system. All or part of the audio processing system may be implemented as special purpose logic circuitry (e.g., an FPGA (field-programmable gate array) and/or an ASIC (application-specific integrated circuit)). All or part of the audio system may be implemented using electronic hardware circuitry that include electronic devices such as, for example, at least one of a processor, a memory, a programmable logic device or a logic gate.

In some aspects, this disclosure may include the language, for example, “at least one of [element A] and [element B].” This language may refer to one or more of the elements. For example, “at least one of A and B” may refer to “A,” “B,” or “A and B.” Specifically, “at least one of A and B” may refer to “at least one of A and at least one of B,” or “at least of either A or B.” In some aspects, this disclosure may include the language, for example, “[element A], [element B], and/or [element C].” This language may refer to either of the elements or any combination thereof. For instance, “A, B, and/or C” may refer to “A,” “B,” “C,” “A and B,” “A and C,” “B and C,” or “A, B, and C.”

While certain aspects have been described and shown in the accompanying drawings, it is to be understood that such aspects are merely illustrative of and not restrictive, and the disclosure is not limited to the specific constructions and arrangements shown and described, since various other modifications may occur to those of ordinary skill in the art. For example, while FIG. 2 shows the speaker driver signal as being one that is to drive a loudspeaker (of the smart speaker), the flow diagram of the dialogue enhancement process in FIG. 1 may be performed in a playback system in which the speaker 108 is not a loudspeaker but instead one of a pair of headphones (where the listener in that case would be wearing the headphones while listening to the sound program while watching the movie on the display of FIG. 2.)

To aid the Patent Office and any readers of any patent issued on this application in interpreting the claims appended hereto, applicants wish to note that they do not intend any of the appended claims or claim elements to invoke 35 U.S.C. 112 (f) unless the words “means for” or “step for” are explicitly used in the claim.

It is well understood that the use of personally identifiable information should follow privacy policies and practices that are recognized as meeting or exceeding industry or governmental requirements for maintaining the privacy of users. Personally identifiable information data should be managed and handled to minimize risks of unintentional or unauthorized access or use, and the nature of authorized use should be clearly indicated to users.

What is claimed is:

1. A method for processing a sound program by a playback system, the method comprising:
a. receiving the sound program;
b. extracting a virtual center channel from the sound program;
c. applying a dynamic range compression and applying a boost to the virtual center channel, to produce a compressed virtual center channel; and
d. producing a speaker driver signal using the compressed virtual center channel.

2. The method of claim 1 wherein
i) applying the boost to the virtual center channel comprises applying a first boost when a system volume is less than a first volume threshold and a second boost when the system volume is more than the first volume threshold, the first boost being greater than the second boost, or
ii) applying the dynamic range compression to the virtual center channel comprises applying a first compression when the system volume is less than a second volume threshold and a second compression when the system volume is more than the second volume threshold, the first compression being different than the second compression.

3. The method of claim 2 wherein i) and ii) are performed in response to the same instance of the system volume.

4. The method of claim 2 wherein when the system volume is greater than a set threshold the second boost is zero dB.

5. The method of claim 1 further comprising:
determining whether the sound program is tagged as being a soundtrack of a movie, wherein the speaker driver signal is produced using the compressed virtual center channel if or in response to determining that the sound program is tagged as being a soundtrack of movie.

6. The method of claim 1 wherein the sound program is in a stereo format having a left channel and a right channel, and extracting the virtual center channel comprises up mixing the left channel and the right channel to produce the virtual center channel.

7. The method of claim 6 wherein the up mixing comprises converting the left channel and the right channel into a multi-channel format.

8. The method of claim 1 wherein the sound program is in a multi-channel surround format that has a center channel, and extracting the virtual center channel comprises taking the center channel to be the virtual center channel.

9. The method of claim 1 wherein i) applying the dynamic range compression is only in a frequency band above 800 Hz or ii) applying the boost is only in the frequency band above 800 Hz.

10. The method of claim 1 wherein a-d are performed by a processor in a smart speaker.

11. The method of claim 10 further comprising in the smart speaker:
receiving an enhanced dialogue indication via a wireless communication network from a digital media player that is executing in a control device, wherein the smart speaker and the control device are in different nodes of the wireless communication network and b-d are performed only when receiving the enhanced dialogue indication.

12. The method of claim 11 wherein the digital media player is being executed by a processor of the control device and is sending the enhanced dialogue indication or a movie mode indication to the smart speaker.

13. The method of claim 10 comprising in the smart speaker:
receiving a movie mode indication via a wireless communication network from a digital media player that is executed in a control device where the smart speaker and the control device are in different nodes of the wireless communication network, wherein b-d are performed in response to receiving the movie mode indication and the sound program is not a system sound.

14. The method of claim 13 wherein the digital media player is executed by a processor of the control device and is sending the movie mode indication to the smart speaker.

15. The method of claim 1 wherein b-d are performed in response to receiving an enhanced dialogue indication, the enhanced dialogue indication having been sent in response to detecting a vocalized question by a user or listener of the playback system, during playback of the sound program.

16. The method of claim 1 wherein b-d are performed in response to receiving an enhanced dialogue indication, the enhanced dialogue indication having been sent in response to detecting acoustic noise in an ambient environment of the playback system exceeds a threshold.

17. The method of claim 1 wherein b-d are performed in response to receiving an enhanced dialogue indication, the enhanced dialogue indication having been sent in response to detecting a user or listener of the playback system has enabled subtitles, during playback of the sound program.

18. The method of claim 1 wherein b-d are performed in response to receiving an enhanced dialogue indication, the enhanced dialogue indication having been sent in response to detecting a current time of day falls within a predetermined schedule.

19. The method of claim 1 wherein b-d are performed in response to receiving an indication that the playback system is in a movie mode of operation, and the sound program is not a system sound.

20. The method of claim 1 wherein a-d are performed by a processor in a control device being one of: a streaming media console, a tablet computer, or a laptop computer.

21. The method of claim 20 further comprising sending the speaker driver signal to drive a speaker of a pair of headphones.

22. The method of claim 1 wherein a-d are performed by a processor in a smart television.
